(19) United States
(12) Patent Application Publication
(10) Pub. No.: US 2024/0313055 A1
(43) Pub. Date: Sep. 19, 2024

(54) SEMICONDUCTOR DEVICE AND POWER CONVERSION DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hirofumi NAGANO, Fujisawa, Kanagawa (JP); Kumiko SATO, Kanazawa, Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/449,848

(22) Filed: Aug. 15, 2023

(30) Foreign Application Priority Data
Mar. 17, 2023 (JP) 2023-043393

(51) Int. Cl. H01L 29/10; H01L 29/40; H01L 29/78

(52) U.S. Cl. CPC H01L 29/1045; H01L 29/404; H01L 29/7824

(57) ABSTRACT

According to an embodiment of the present invention, a semiconductor device includes a first region, a second region, a third region, and a gate region. The first region is of first conductive type and formed on a surface layer on one main surface side of the semiconductor substrate. The second region is of second conductive type and formed in a different region of the surface layer from the first region. The third region is formed between the first region and the second region on the surface layer, and has a predetermined impurity concentration distribution. The gate region is formed at one end of the third region through a gate oxide layer. The third region includes a first change region of the impurity concentration distribution corresponding to a position of the gate region.

### CROSS-REFERENCE TO RELATED APPLICATIONS

This application is based upon and claims the benefit of priority from the prior Japanese Patent Application No. 2023-043393, filed on Mar. 17, 2023 the entire contents of which are incorporated herein by reference.

### FIELD

Embodiments of the present invention relate to a semiconductor device and a power conversion device.

### BACKGROUND

In a semiconductor device such as a lateral diffused MOSFET, its breakdown voltage is increased by extending a depletion layer region in a drift layer. On the other hand, as the thickness of an active layer in which the drift layer is formed increases, a special process is needed to increase the thickness of the active layer.

### BRIEF DESCRIPTION OF THE DRAWINGS

FIG. 1 are a cross-sectional view and a graph illustrating a semiconductor device according to the present embodiment;

FIG. 2 are a cross-sectional view and a graph illustrating a semiconductor device according to a second embodiment;

FIG. 3 illustrate simulation results when using field plates;

FIG. 4 is a circuit diagram illustrating a first connection mode of the semiconductor device in a power conversion device; and

FIG. 5 is a circuit diagram illustrating a second connection mode of the semiconductor device in the power conversion device.

### DETAILED DESCRIPTION

According to the present embodiment, a semiconductor device includes a first region, a second region, a third region, and a gate region. The first region is a first conductive type formed on a surface layer on one main surface side of a semiconductor substrate. The second region is a second conductive type formed in a different region of the surface layer from the first region. The third region is formed between the first region and the second region on the surface layer, the third region having a predetermined impurity concentration distribution. The gate region is formed at one end of the third region through a gate oxide layer. The third region includes a first change region of the impurity concentration distribution corresponding to the position of the gate region.

Embodiments of the present invention are hereinafter explained with reference to the accompanying drawings. While characteristic configurations and operations of a semiconductor device and a power conversion device are mainly explained in the following embodiments, the semiconductor device and the power conversion device may include configurations and operations omitted in the following explanations.

### First Embodiment

Embodiments of the present invention will be explained below with reference to the drawings. The drawings are schematic and conceptual. The relation between the thickness and the width of each part, the ratio of size among the parts, and the like do not necessarily match those of actual products. Even in a case where the same parts are represented, the dimensions and the ratios thereof are represented differently depending on the drawings in some cases. In the specification of the present application and the respective drawings, the same elements as those already explained are denoted by like reference characters and detailed explanations thereof are omitted as appropriate.

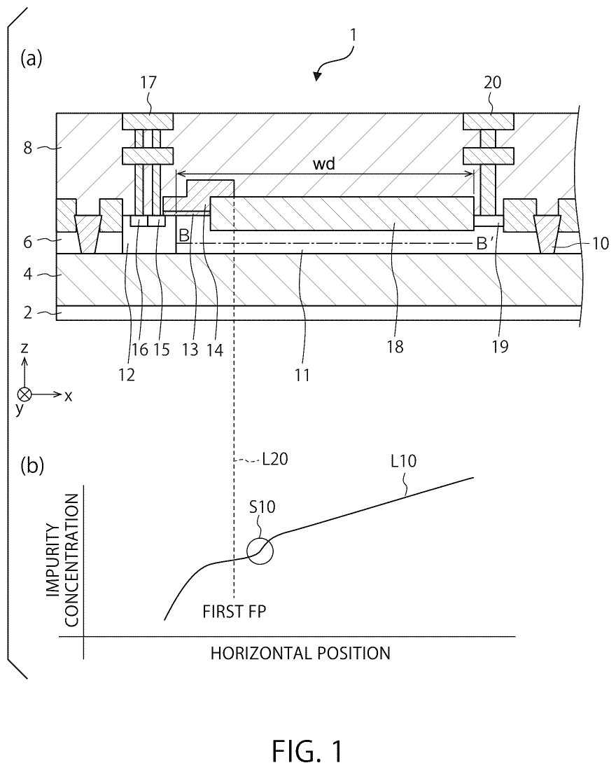

FIG. 1(a) is a cross-sectional view illustrating a semiconductor device 1 according to the present embodiment. As illustrated in FIG. 1(a), the semiconductor device 1 according to the present embodiment is, for example, an LDMOSFET (Lateral Defused Metal Oxide Semiconductor Field Effect Transistor). FIG. 1(b) is a graph illustrating an impurity concentration nd in a drift layer 11. The horizontal axis represents the position in a lateral direction of the drift layer 11, while the vertical axis represents the impurity concentration nd. That is, FIG. 1(b) is a graph illustrating the impurity concentration nd relative to a position along a line B-B′ of FIG. 1(a). FIG. 1(a) illustrates an example of an n-channel LDMOSFET with a breakdown voltage of 600 volts or higher. The LDMOSFET may also be referred to as “lateral MOSFET” or “lateral MOS transistor”.

As illustrated in FIGS. 1, the semiconductor device 1 includes a support substrate 2, a first insulating layer 4, a semiconductor substrate 6, and a second insulating layer 8. These substrates and layers are formed into, for example, an SOI (Silicon On Insulator) substrate. That is, the support substrate 2, the first insulating layer 4, and the semiconductor substrate 6 constitute the SOI substrate. In the present embodiment, the z-direction is directed to the upper side, while the x-direction perpendicular to the z-direction is defined as a lateral direction. The semiconductor device 1 further includes an element isolation trench 10, the drift layer 11, a p-type well region 12, a gate oxide film 13, a gate electrode 14, a high-concentration n+ layer 15, a high-concentration p+ layer 16, an electrode 17, a field insulating film (LOCOS) 18, a high-concentration n+ layer 19, and an electrode 20.

The first insulating layer 4 (BOX) is a buried oxide film and formed on an upper main surface of the support substrate 2. The first insulating layer 4 has a thickness of, for example, 3 μm or less.

The semiconductor substrate 6 is formed on the upper side of the first insulating layer 4. The semiconductor substrate 6 is, for example, an n-type substrate. The n-type substrate is an active layer (active region). The semiconductor substrate 6 has a thickness of, for example, 2 μm or less. The second insulating layer 8 is formed on the upper side of the semiconductor substrate 6.

The semiconductor substrate 6 is isolated by the element isolation trench 10. That is, the active layer is insulated by the element isolation trench 10, the first insulating layer 4, and the second insulating layer 8. It is possible to mixedly mount, for example, a plurality of LDMOSFETs and CMOSFETs (Complementary MOSFETs) and other elements together on the support substrate 2.

In the semiconductor substrate 6, the drift layer 11, the p-type well region 12, the high-concentration n+ layer 15, the high-concentration p+ layer 16, a partial region of the field insulating film 18, and the high-concentration n+ layer 19 are formed. That is, the p-type well region 12 is a first region of first conductive type (p) formed on a surface layer on one main surface side of the semiconductor substrate 6.

The high-concentration n+ layer 19 is a second region of second conductive type (n) formed in a different region of the surface layer from the high-concentration p+ layer 16. The drift layer 11 is formed between the p-type well region 12 and the high-concentration n+ layer 19 on the surface layer, and has a predetermined impurity concentration distribution. The drift layer 11 according to the present embodiment corresponds to a third region. The drift layer 11 is described later in detail.

The high-concentration n+ layer 15 is a fourth region of second conductive type (n) formed adjacent to the first region that is the p-type well region 12. The high-concentration p+ layer 16 is a fifth region of first conductive type (p) formed adjacent to the high-concentration n+ layer 15 on the surface layer on one main surface side of the semiconductor substrate 6.

The gate electrode 14 is formed on the upper side of the p-type well region 12 through the gate oxide film 13. A surface layer of the p-type well region 12 and a surface layer of the high-concentration n+ layer 15 are partially connected to the gate oxide film 13. The gate electrode 14 is made of, for example, polysilicon (poly-Si). A contact region of the p-type well region 12 in contact with the gate oxide film 13 serves as a channel region where electric charges are generated by an inversion layer of a MOS capacitor.

In this manner, the high-concentration n+ layer 15 adjacent to the channel region, and the high-concentration p+ layer 16 (p+ contact) that feeds power to the p-type well region 12 are connected to the electrode 17, forming a source region. The high-concentration n+ layer 19 is formed on a surface layer of the drift layer 11 with a predetermined distance Wd from the channel region through the field insulating film 18. The electrode 20 is connected to the high-concentration n+ layer 19, forming a drain region (n+ contact).

As described above, the second insulating layer 8 is formed in such a manner as to cover the semiconductor substrate 6, the gate electrode 14, and the field insulating film 18. In the second insulating layer 8, a plurality of electrodes 17 and 20 are formed, penetrating the second insulating layer 8.

It is possible to constitute a p-channel LDMOSFET by interchanging the n-type region and the p-type region of the n-channel LDMOSFET illustrated in FIG. 1(a). That is, the drift layer 11 is changed to a p-type drift layer, the well region 12 is changed to an n-type well region, the layer 15 is changed to a high-concentration p+ layer, the layer 16 is changed to a high-concentration n+ layer, and the layer 19 is changed to a high-concentration p+ layer. That is, it is supposed in the p-channel LDMOSFET that a well layer is of n-type while source, drift, and drain layers are of p-type, and halls are current carriers.

### (Operation)

When a gate voltage is applied to the gate electrode 14, inversion-layer electrons are generated in the channel region of the p-type well region 12. A voltage is applied between the electrodes 17 and 20, so that the inversion-layer electrons move between the source and the drain through the drift layer 11, and consequently a current flows from the drain toward the source.

On the other hand, when the gate voltage is lower than a threshold, an inversion layer is not formed, and consequently a current does not flow even when the voltage is applied between the electrodes 17 and 20. In the present embodiment, a condition that the gate voltage is equal to or higher than the threshold is referred to as “on state”, while a condition that the gate voltage is lower than the threshold is referred to as “off state”.

When a high voltage of, for example, 600 volts is applied between the source and the drain, a depletion layer grows in the drift layer 11 from its junction region with the p-type well region 12. The depletion layer grows in this manner, so that an electric field is relaxed and this makes it possible to prevent an occurrence of avalanche breakdown. That is, as the depletion-layer region is increased, equipotential lines inside the drift layer 11 are more widely spaced, and accordingly the electric field can be more relaxed. It is thus possible to increase the breakdown voltage.

When a disturbance of the electric field occurs at a specific location in the depletion layer, the disturbance results in a region where equipotential lines are densely spaced and there is a likelihood of causing avalanche breakdown. In view of that, it is required to evenly space equipotential lines in the depletion layer in order to increase the breakdown voltage.

When the impurity concentration nd in the drift layer 11 is increased, it is possible to decrease an on-resistance between the source and the drain in the on-state. On the other hand, when the impurity concentration nd in the drift layer 11 is increased, the depletion layer extending in the direction from the junction region of the drift layer 11 with the p-type well region 12 toward the drain has a reduced distance. Consequently, equipotential lines are less widely spaced, so that avalanche breakdown is more likely to occur. A high electric field tends to be generated particularly in the vicinity of the source region. As described above, there is a trade-off relationship between a decrease in the on-resistance and an increase in the breakdown voltage. For example, when the drift layer 11 is divided into two layers and one of the layers has a high concentration (see Patent Literature 1), growth of the depletion layer is suppressed in the high-concentration-side layer, which may cause equipotential lines to be less widely spaced. That is, there may be a likelihood of avalanche breakdown occurring on one layer side.

Therefore, in the present embodiment, in consideration of an electric-field intensity distribution, the impurity concentration nd in the drift layer 11 is changed. That is, based on the electric field formed in the drift layer 11 according to the present embodiment, a change region of the impurity concentration distribution is formed. In other words, the impurity concentration nd is distributed in such a manner that the equipotential lines inside the drift layer 11 are evenly spaced, while the increase in on-resistance is suppressed.

### (Concentration Distribution in Drift Layer 11)

Referring back to FIG. 1(b), a line L10 illustrates the impurity concentration nd relative to a position between B and B′ in FIG. 1(a). As illustrated by the line L10, the impurity concentration nd is increased from the source side toward the drain side. For example, the impurity concentration nd is monotonically increased from the source side toward the drain side. For example, a first-order differential value of the impurity concentration nd with respect to the position in the lateral direction on the line L10 is defined as a positive value.

Consequently, due to the concentration distribution according to the electric-field intensity, equipotential lines are evenly spaced, and the depletion layer easily grows toward the drain side. Also, a uniform concentration is obtained at the same position in the drift layer 11. The semiconductor substrate 6 has a thickness of, for example, 3 μm or less. The semiconductor device 1 according to the present embodiment has the drift layer 11 formed into a thickness of, for example, 2 μm or less. Accordingly, when the drift layer 11 is doped with impurities, it is easier for the drift layer 11 to have a uniform concentration at the same position.

With this structure, equipotential lines are evenly spaced at the same position, and avalanche breakdown is less likely to occur. This structure also makes it possible to reduce the impurity concentration nd in its entirety, and the on-resistance is also reduced.

On the line L10, the concentration distribution is changed in consideration of factors that disturb the electric-field intensity distribution. For example, a first line L20 corresponding to an end portion of the gate electrode 14 is a factor that causes a non-uniform electric-field distribution in the drift layer 11. Due to this factor, a change region S10 of the concentration distribution is defined corresponding to the position of the end portion of the gate electrode 14. The change region S10 of the concentration distribution is set to such a concentration as to reduce the disturbance of the electric field. With this setting, equipotential lines are evenly spaced, and avalanche breakdown is less likely to occur. More specifically, the effective dose amount on the source side with reference to the change region S10 is equal to 1×10¹² to 5×10¹²/cm², while the effective dose amount at the drain-side end portion is equal to 5×10¹² to 3×10¹³/cm². This makes it possible to increase the breakdown voltage to, for example, 600 volts or higher, while suppressing the increase in on-resistance. The change region of the concentration distribution refers to a region where a second-order differential value of the impurity concentration nd with respect to the position in the lateral direction on the line L10 is positive. This change region is a so-called downward convex region. In the present embodiment, for example, a change from an upward convex region to a downward convex region, or a change from a downward convex region to an upward convex region may be sometimes referred to as “change in concentration distribution”.

As explained above, in the present embodiment, the impurity concentration nd in the drift layer 11 is set according to the electric-field intensity distribution in the drift layer 11. With this setting, even when there is a disturbance of the electric field distribution or there is a positional change in the electric-field intensity, equipotential lines are still evenly spaced in the depletion layer, and avalanche breakdown is less likely to occur. The impurity concentration nd is monotonically increased from the source side toward the drain side. Consequently, due to the concentration distribution according to the electric-field intensity, equipotential lines are evenly spaced, and the depletion layer easily grows toward the drain side.

### Second Embodiment

A semiconductor device 1a according to a second embodiment is different from the semiconductor device 1 according to the first embodiment in that the semiconductor device 1a further includes a field plate Fp that provides a uniform electric-field distribution in the drift layer 11.

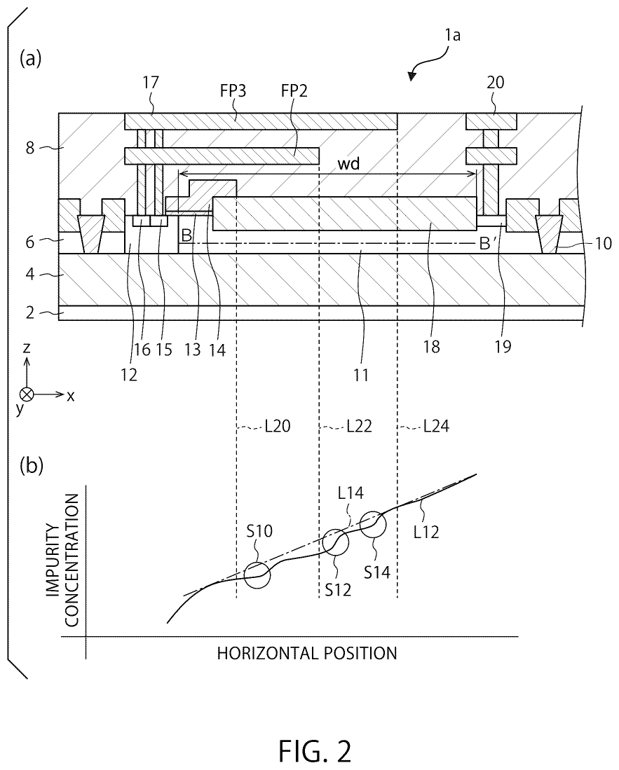

FIG. 2(a) is a cross-sectional view illustrating the semiconductor device 1a according to the second embodiment. As illustrated in FIG. 2(a), the semiconductor device 1a according to the present embodiment is, for example, the LDMOSFET 1. As illustrated in FIG. 2(a), the semiconductor device 1a according to the present embodiment further includes field plates Fp2 and Fp3. FIG. 2(b) is a graph illustrating the impurity concentration nd in the drift layer 11. The horizontal axis represents the position in the lateral direction of the drift layer 11, while the vertical axis represents the impurity concentration nd. As illustrated in FIG. 2(a), the field plates Fp2 and Fp3 according to the present embodiment generate an electric field so as to provide a uniform electric-field intensity distribution in the drift layer 11. The field plate Fp2 according to the present embodiment corresponds to a first electric field generator, while the field plate Fp3 corresponds to a second electric field generator.

A line L12 in FIG. 2(b) illustrates the impurity concentration nd relative to a position between B and B′ in FIG. 2(a). A line L14 shows, for example, a monotonically increasing linear line. A second line L22 and a third line L24 show the drain-side end portions of the field plates Fp2 and Fp3, respectively. That is, the first line L20 passes through the end portion of the gate electrode 14 located toward the high-concentration n+ layer 19, and is perpendicular to the surface layer of the semiconductor substrate 6. The second line L22 passes through an end portion of the field plate Fp2 located toward the high-concentration n+ layer 19, and is perpendicular to the surface layer of the semiconductor substrate 6. The third line L24 passes through an end portion of the field plate Fp3 located toward the high-concentration n+ layer 19, and is perpendicular to the surface layer of the semiconductor substrate 6.

For example, the effective dose amount on the source side with reference to a first change region S10 is equal to 1×10¹² to 5×10¹²/cm², while the effective dose amount on the drain side with reference to a second change region S12 is equal to 5×10¹² to 3×10¹³/cm². The first change region S10 is at a position of 30 to 80% of the distance between the first line L20 and the second line L22. The second change region S12 is at a position of 30 to 50% of the distance between the second line L22 and the third line L24. A third change region S14 is at a position of 60 to 80% of the distance between the second line L22 and the third line L24. These numeric values are merely examples and are not limited thereto.

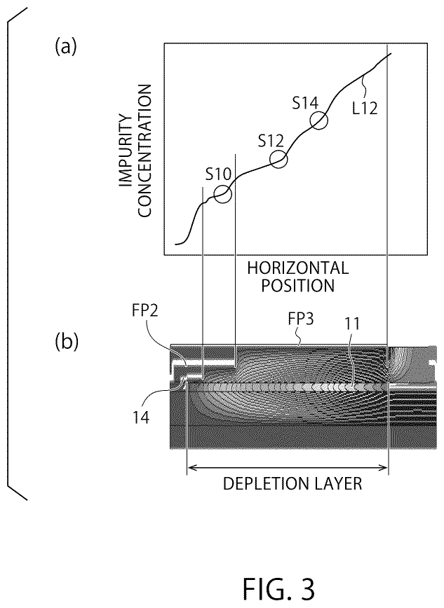

As illustrated in FIG. 2(b), the change regions S12 and S14 of the concentration distribution are defined respectively at positions corresponding to the end portions of the field plates Fp2 and Fp3. As illustrated in FIG. 3 described later, it is possible to control the electric-field intensity distribution in the drift layer 11 by the positions of the field plate Fp2 and the field plate Fp3 and their respective electric field intensities. In this case, for example, when the change regions S12 and S14 of the concentration distribution are defined between the end portion of the field plate Fp2 and the end portion of the field plate Fp3, it is thus possible to decrease the concentration distribution and evenly space the equipotential lines of the electric-field intensity. For example, since there is a change in the electric-field intensity at the end portions of the field plates Fp2 and Fp3, the change regions S12 and S14 of the concentration distribution are defined at positions corresponding to the end portions of the field plates Fp2 and Fp3. This makes it possible to evenly space the equipotential lines of the electric-field intensity more efficiently. As described above, the line L12 shows a concentration that is decreased relative to that shown by the line L14. That is, the impurity concentration nd is further decreased in its entirety, compared to the semiconductor device 1 according to the first embodiment. That is, a non-uniform electric-field intensity distribution in the drift layer 11, which is caused by decreasing the impurity concentration nd, is controlled to become uniformed by an electric field generated by the field plates Fp2 and Fp3.

More specifically, even when the impurity concentration in the drift layer 11 is decreased in the change regions S10, S12, and S14 of the concentration distribution, a region with dense equipotential lines is still not formed in the drift layer 11. With this structure, even when the impurity concentration in the drift layer 11 is further decreased, it is still possible to suppress formation of a region with dense equipotential lines in the drift layer 11. This makes it possible to maintain or increase the breakdown voltage.

FIG. 3 are a graph and a diagram illustrating simulation results obtained when the field plates Fp2 and Fp3 are used. FIG. 3(a) is a graph corresponding to FIG. 2(b). FIG. 3(b) illustrates the electric field in the semiconductor device 1 by using equipotential lines. Since FIG. 3 simply illustrate simulation results, the dimensions, ratios, and other features in FIG. 3 are different from those illustrated in FIG. 2.

As illustrated in FIG. 3(b), a depletion layer is formed from the junction portion to the drain region. Even when the impurity concentration in the drift layer 11 is further decreased, the equipotential lines are still evenly spaced due to the electric field generated by the field plates Fp2 and Fp3. This makes it possible to maintain or increase the breakdown voltage as described above.

As explained above, in the present embodiment, a uniform electric field is formed in the drift layer 11 by using the field plates Fp2 and Fp3. With this structure, even when the impurity concentration in the drift layer 11 is further decreased in stages relative to the linear increase, it is still possible to evenly space the equipotential lines in the drift layer 11. This makes it possible to maintain or increase the breakdown voltage.

### Third Embodiment

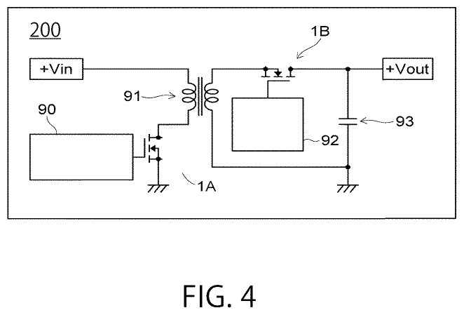

In a third embodiment, an example of a connection mode of the semiconductor device 1 is described. FIG. 4 is a circuit diagram illustrating a first connection mode of the semiconductor device 1 in a power conversion device. FIG. 4 illustrates a circuit diagram of an AC-DC converter 200 as an example of the power conversion device. In the AC-DC converter 200, a semiconductor device 1A is an n-channel LDMOSFET and connected to a control circuit 90 and a transformer 91. A semiconductor device 1B is a p-channel LDMOSFET and connected to the transformer 91 and a drive circuit 92. A capacitor 93 is connected to the semiconductor device 1B and the transformer 91. In the AC-DC converter 200, an input AC voltage is converted to a DC voltage to be output.

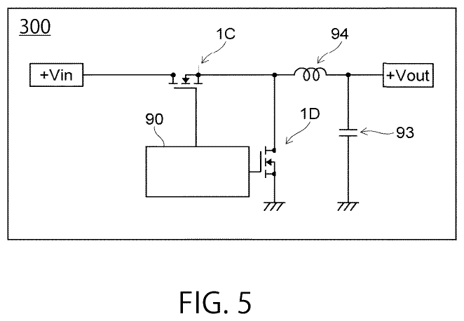

FIG. 5 is a circuit diagram illustrating a second connection mode of the semiconductor device 1 in a power conversion device. FIG. 5 illustrates a circuit diagram of a DC-DC converter 300 as an example of the power conversion device. In the DC-DC converter 300, a semiconductor device 1C is an n-channel LDMOSFET, provided on the high-potential side, and connected to the control circuit 90 and a coil 94. A semiconductor device 1D is a p-channel LDMOSFET, provided on the low-potential side, and connected to the control circuit 90. The semiconductor device 1D is connected between the semiconductor device 1C and the coil 94. The capacitor 93 is connected to the coil 94. In the DC-DC converter 300, an input DC voltage is converted to another DC voltage to be output. FIGS. 4 and 5 merely illustrate examples of the connection mode of the semiconductor device 1, and the connection mode is not limited to these examples. For another example, it is possible to use the semiconductor device 1 in a drive module of a three-phase brushless motor. In this case, six units of the semiconductor devices 1 according to the present embodiment are used as a high-side element and a low-side element for three U-, V-, and W-phases, so that it is possible to constitute the semiconductor devices 1 as switching elements that operate within a high-level voltage range between, for example, 0 and 600 volts. As described above, it is possible to use the semiconductor device 1 according to the present embodiment as a switching element to be used in a power conversion device (for example, a converter or an inverter) that needs a high breakdown voltage.

Furthermore, it is possible to mixedly mount the semiconductor device 1 according to the present embodiment together with other elements on an IC (Integrated Circuit). Therefore, it is possible to integrate functions on the IC such as a power converting function with a high breakdown voltage in a power conversion device or the like, in addition to a calculating function.

While certain embodiments of the present invention have been described, these embodiments have been presented by way of example only, and are not intended to limit the scope of the invention. The novel embodiments described herein may be embodied in a variety of other forms, and various omissions, substitutions, and changes may be made without departing from the spirit of the invention. These embodiments and modifications thereof would fall within the scope and spirit of the invention, and would fall within the invention described in the accompanying claims and their equivalents.

1. A semiconductor device comprising:
a semiconductor substrate;
a first region of first conductive type formed on a surface layer on one main surface side of the semiconductor substrate;
a second region of second conductive type formed in a different region of the surface layer from the first region;
a third region formed between the first region and the second region on the surface layer, the third region having a predetermined impurity concentration distribution; and
a gate region formed at one end of the third region through a gate oxide layer, wherein
the third region includes a first change region of the impurity concentration distribution corresponding to a position of the gate region.

2. The device of claim 1, wherein the third region includes a plurality of change regions of the impurity concentration distribution based on an electric field formed in the third region.

3. The device of claim 2, wherein there are three or more change regions of the impurity concentration distribution.

4. The device of claim 2, wherein the impurity concentration distribution increases from the one end of the third region toward the other end thereof.

5. The device of claim 4, wherein the impurity concentration distribution monotonically increases from the one end of the third region toward the other end thereof.

6. The device of claim 2, wherein the change regions of the impurity concentration distribution are formed in such a manner that equipotential lines of an electric field formed in the third region are evenly spaced.

7. The device of claim 2, further comprising a first electric field generator capable of generating an electric field in the third region, wherein
a second change region of the impurity concentration distribution is formed corresponding to a position of an end portion of the first electric field generator.

8. The device of claim 7, further comprising a second electric field generator capable of generating an electric field in the third region, wherein
a third change region of the impurity concentration distribution is formed corresponding to a position of an end portion of the second electric field generator.

9. The device of claim 8, wherein an effective dose amount on one end side with reference to the first change region is equal to 1×10¹² to 5×10¹²/cm².

10. The device of claim 9, wherein an effective dose amount on the other end side with reference to the third change region is equal to 5×10¹² to 3×10¹³/cm².

11. The device of claim 10, wherein
the first change region is at a position of 30 to 80% of a distance between a first line and a second line, the first line passing through an end portion of the gate region, the end portion being located toward the second region, the first line being perpendicular to the surface layer, the second line passing through an end portion of the first electric field generator, the end portion being located toward the second region, the second line being perpendicular to the surface layer,
the second change region is at a position of 30 to 50% of a distance between the second line and a third line, the third line passing through an end portion of the second electric field generator, the end portion being located toward the second region, the third line being perpendicular to the surface layer, and
the third change region is at a position of 60 to 80% of the distance between the second line and the third line.

12. The device of claim 11, wherein the first region corresponds to a well region, the second region corresponds to a drain region, and the third region corresponds to a drift layer.

13. The device of claim 12, further comprising:
a fourth region of second conductive type formed adjacent to the first region on the surface layer;
and a fifth region of first conductive type formed adjacent to the fourth region on the surface layer, wherein
the first region and the fourth region are in contact with the gate oxide layer.

14. The device of claim 13, further comprising:
a first insulating layer formed on a main surface of the semiconductor substrate opposite to the main surface side thereof;
a support substrate configured to support the first insulating layer; and
a second insulating layer formed on the main surface side of the semiconductor substrate, wherein
the first electric field generator and the second electric field generator are formed in the second insulating layer.

15. The device of claim 14, wherein the semiconductor substrate is an active layer and has a thickness of 2 μm or less.

16. The device of claim 15, wherein the semiconductor substrate, the second insulating layer, and the support substrate are an SOI substrate.

17. A power conversion device comprising the semiconductor device according to claim 1.
